(19) United States
(12) Patent Application Publication
(10) Pub. No.: US 2026/0267529 A1
(43) Pub. Date: Sep. 10, 2026

(54) RADIATION TOLERANT DATA STORAGE

(71) Applicant: COLOSSUS COMPUTING, INC., Oakland, CA (US)

(72) Inventors: Alex Swehla, Oakland, CA (US); Jason Cerundolo, Oakland, CA (US); Alex Hiam, San Francisco, CA (US)

(21) Appl. No.: 19/662,418

(22) Filed: Apr. 29, 2026

Related U.S. Application Data
(63) Continuation of application No. PCT/US2024/054252, filed on Nov. 1, 2024.
(60) Provisional application No. 63/547,312, filed on Nov. 3, 2023.

(51) Int. Cl. G06F 3/06

(52) U.S. Cl. CPC G06F 3/0619; G06F 3/0659; G06F 3/0679

(57) ABSTRACT

A radiation tolerant data storage apparatus and method. The radiation tolerant data storage apparatus and method can direct and store redundant copies of data in different physical locations to reduce the likelihood that a single radiation particle damages corresponding portions of the multiple copies of data. The radiation tolerant data storage apparatus and method includes a controller that arranges for multiple copies of data to be stored in a manner that reduces collinearity and detect if one copy has been damaged. The copies are preferably stored at physical locations that minimize or otherwise completely avoid the ability for a single radiation particle to damage or flip the same bit in each of the multiple copies of data. Most preferably, numerous other radiation hardening techniques can also be used to provide further radiation tolerance to the system and method.

### CROSS-REFERENCE TO RELATED APPLICATIONS

This application is a continuation application of PCT Application No. PCT/US2024/054252, entitled “RADIATION TOLERANT DATA STORAGE” filed on Nov. 1, 2024, which itself claims priority to and the benefit of the filing of U.S. Provisional Patent Application No. 63/547,312, entitled “Radiation Tolerant Data Storage”, filed on Nov. 3, 2023, and the specification and claims (if any) thereof are incorporated herein by reference.

### STATEMENT REGARDING FEDERALLY SPONSORED RESEARCH OR DEVELOPMENT

This invention was made with government support under Contract No. 80NSSC22PD248 awarded by NASA Shared Service Center. The government has certain rights in the invention.

### BACKGROUND OF THE INVENTION

Embodiments of the present invention relate to radiation tolerant data storage. More particularly, embodiments of the present invention relate to data storage wherein redundant copies of data are stored in physical locations that reduce the likelihood that a single radiation particle can damage corresponding portions of the multiple copies of data.

Modern Earth observation satellites generate ever-increasing quantities of data, which must be temporarily stored onboard between collection and downlink. This is true for optical imaging but is even more so for synthetic aperture radar (“SAR”) and hyperspectral imaging. Satellite manufacturers who are currently building constellations for low Earth orbit (“LEO”) are also using terrestrial solid state drives (“SSDs”) in their satellites. Such drives are intended for use in consumer electronics or data centers and are optimized for performance and cost. However, due to the harmful radiation in the space environment, such controllers can fail early and without warning. There is thus a present need for a dual-redundant controller architecture implemented on radiation tolerant hardware, which protects data from encounters with radiation and ensures that the usable life of the data storage exceeds that of the mission parameters.

### BRIEF SUMMARY OF EMBODIMENTS OF THE PRESENT INVENTION

Embodiments of the present invention relate to a radiation tolerant method for storing data that includes providing a controller, providing a non-transitory first data storage, providing a non-transitory second data storage, programming the controller with knowledge of a spatial relationship of the non-transitory first data storage and the non-transitory second data storage, and the controller directing copies of the data be stored at a first location of the non-transitory first data storage and at a second location of the non-transitory second data storage while reducing collinearity of the copies based at least on the spatial relationship, data storage availability of the non-transitory first data storage and data storage availability of the non-transitory second data storage, and a current ability of each of the non-transitory first data storage and the non-transitory second data storage to store a respective copy of the data at the first location and the second location.

In one embodiment, the controller reduces collinearity by maximizing a distance between the first location and the second location. In the method, providing the non-transitory first data storage can include providing a solid state data storage, which itself can optionally include NAND data storage. The controller can query a data storage manager of at least one of the non-transitory first data storage and the non-transitory second data storage. The method can further include uploading the data into the controller from a host interface.

Optionally, a data storage manager of the non-transitory first data storage and a data storage manager of the non-transitory second data storage can each add an error check code when the copies of the data are stored. In one embodiment, the method can also include mapping addresses of the first location and the second location with an abstract block address and can include presenting the abstract block address to a host device. The step of providing a controller can include providing a flash redundancy controller. The controller can also optionally monitor for a signature of a single event latch-up.

Embodiments of the present invention relates to a radiation tolerant data storage apparatus that includes a controller, a non-transitory first data storage, a non-transitory second data storage, the controller programmed with data describing a spatial relationship of the non-transitory first data storage and the non-transitory second data storage, the controller including instructions which cause it to direct that copies of the data be stored at a first location of the non-transitory first data storage and at a second location of the non-transitory second data storage while reducing collinearity of the copies based at least on: the spatial relationship, data storage availability of the non-transitory first data storage and data storage availability of the non-transitory second data storage, and a current ability of each of the non-transitory first data storage and the non-transitory second data storage to store a respective copy of the data at the first location and the second location.

At least one of the non-transitory first data storage and non-transitory second data storage includes solid state data storage. The solid state data storage comprises NAND data storage. The controller can be a flash redundancy controller. The non-transitory first data storage can include a first memory manager and the non-transitory second data storage can include a second memory manager.

The first memory manager and the second memory manager can be configured to perform data error checking operations. The non-transitory first data storage is disposed on a first side of a printed circuit board and the non-transitory second data storage can be disposed on a second side of the printed circuit board. The controller can assign an abstract block address for a block address of the first location and a block address of the second location. In one embodiment, the apparatus can include code stored on a non-transitory computer readable medium causing the controller to monitor for a signature of a single event latch-up.

Objects, advantages and novel features, and further scope of applicability of the present invention will be set forth in part in the detailed description to follow, taken in conjunction with the accompanying drawings, and in part will become apparent to those skilled in the art upon examination of the following, or may be learned by practice of the invention. The objects and advantages of the invention may be realized and attained by the instrumentalities and combinations particularly pointed out in the appended claims.

### BRIEF DESCRIPTION OF THE SEVERAL VIEWS OF THE DRAWINGS

The accompanying drawings, which are incorporated into and form a part of the specification, illustrate one or more embodiments of the present invention and, together with the description, serve to explain the principles of the invention. The drawings are only for the purpose of illustrating one or more embodiments of the invention and are not to be construed as limiting the invention. In the drawings:

FIG. 1 is a drawing which illustrates a radiation tolerant data storage device, according to an embodiment of the present invention;

FIG. 2 is a drawing of a block diagram that illustrates radiation tolerant data storage, according to an embodiment of the present invention;

FIG. 3 is a simplified block diagram of primary components of a radiation tolerant data storage device, according to an embodiment of the present invention;

FIG. 4 is a drawing which illustrates a radiation tolerant data storage device which is implemented in a PC104 form factor, according to an embodiment of the present invention;

FIG. 5 is a drawing which illustrates data connections of major components of a radiation tolerant data storage device, according to an embodiment of the present invention;

FIG. 6 is a drawing which illustrates an address translation diagram for groupings of components of a radiation tolerant data storage device, according to an embodiment of the present invention;

FIG. 7 is a diagram which illustrates a power sequencing algorithm for a power supply in a radiation tolerant data storage device, according to an embodiment of the present invention;

FIG. 8 is a drawing which illustrates an example of how data can be spatially positioned with respect to a printed circuit board in order to reduce or otherwise minimize the likelihood of destruction of all copies of data due to a single radiation particle, according to an embodiment of the present invention;

FIG. 9 is a drawing which illustrates an example of a configuration for arrangement of memory with respect to a printed circuit board, according to an embodiment of the present invention; and

FIG. 10 is a drawing of a flow chart which illustrates a process used to reduce collinearity of stored data according to an embodiment of the present invention.

### DETAILED DESCRIPTION OF THE INVENTION

An embodiment of the present invention relates to a radiation-tolerant computation storage device. This radiation-tolerant computation storage device preferably provides high-capacity solid state storage through the use of not-and gates (“NAND”), which can include three dimensional (“3D”) NAND technology with flash-controller implementation. The radiation-tolerant computation storage device is preferably configured to mitigate the adverse effects of radiation, which can include for example, high levels of radiation that are encountered by space-based satellites, while providing high performance with low size, weight, and power (“SWaP”).

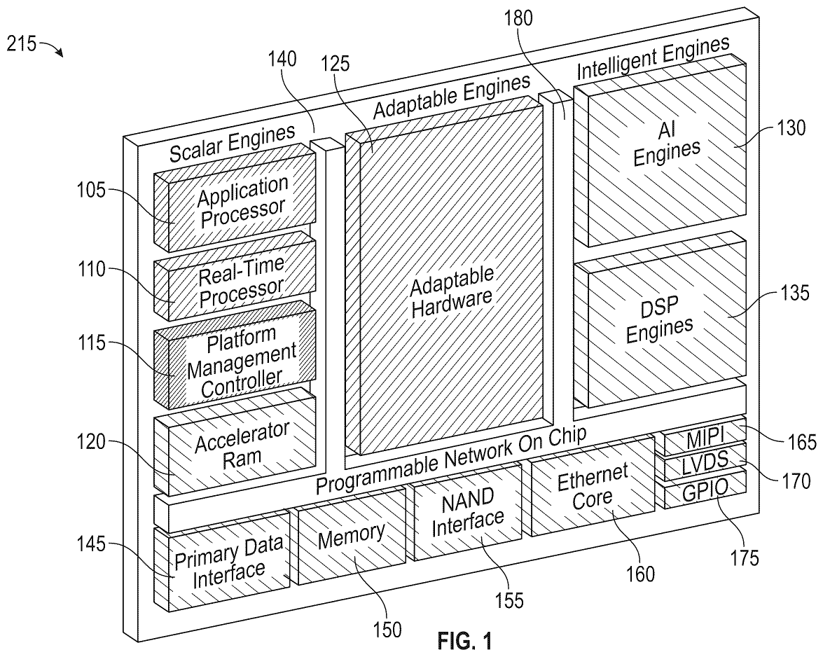

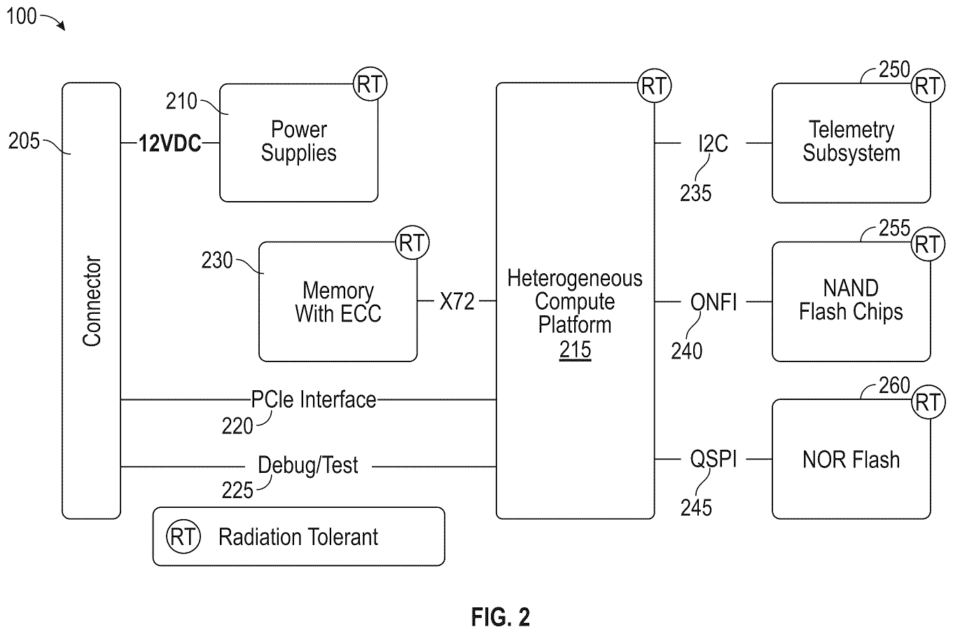

Referring now to the figures, FIG. 1 illustrates heterogenous compute platform 215 of computation storage device 100 (see FIG. 2). Compute platform 215, which preferably includes scalar engines, adaptable engines, and intelligent engines. Scalar engines can include, but are not limited to, application processor 105, real-time processor 110, platform management controller 115, and accelerator random-access memory (“RAM”) 120. Adaptable engines can include, but are not limited to, adaptable hardware 125. Intelligent engines can include, but are not limited to, artificial intelligence (“AI”) engine 130 and digital signal processor (“DSP”) engine 135. Application processor 105 and real-time processor 110 can be a dual or multi-core processor. In addition, heterogeneous compute platform 215 preferably provides onboard computer resources with both general purpose and AI-enabled processors attached to the flash memory to accelerate IO intensive workloads by co-locating them with the storage (see FIG. 1). This allows for the generation of data products on the storage device itself, thereby reducing processing time and effectively increasing the bandwidth between computation storage device 100 and a host device.

Heterogeneous compute platform 215 simplifies integration by using printed circuit board (“PCB”) 140. In one embodiment, PCB 140 is preferably an industry standard form factor, which can include for example PC104. PCB 140 also preferably houses primary data interface 145, memory 150, NAND Interface 155, ethernet cores 160, mobile industry processor interface (“MIPI”) 165, low voltage differential signaling (“LVDS”) 170, general-purpose input/output (“GPIO”) 175, and programmable network 180. Primary data interface 145 can include Non-volatile Memory Express (“NVMe”) protocol, most preferably over a Peripheral Component Interconnect Express (“PCIe”) interface. However, it is possible to use a different form factor, different data interface, and/or a different connection interface if desired. Memory 150 is preferably at least about 2 terabytes (“TB”) of usable space. This is preferably not raw capacity, but instead preferably accounts for the redundancy and overprovisioning to facilitate reliability. Optionally, memory 150 of, for example, about 6 TB or more can be provided. Memory 150 can include double data rate fourth generation (“DDR4”), but preferably includes low power double data rate fourth generation (“LPDDR4”). The total data speed includes sequential reads and write speeds that support modern Earth observation workloads-most preferably with about 2,000 and about 1,000 megabytes per second (“MB/s”) respectively. However, data speed of NAND Interface 155 can exceed 2,000 MB/s. In one embodiment, computation storage device 100 can include Dual Core Lock-Step (“DCLS”) and Triple Modular Redundant (“TMR”) microcontrollers. This allows the implementation and testing of Inter-Processor communication between the two redundant strings of hardware. Open NAND Flash Interface (“ONFI”) can also optionally be used. Compute platform 215 preferably includes a higher speed NAND interface 155 (for example NV-DDR3 timing mode 12, having a speed of at least about 1.2 GT/s per pin), as well as a separate power supply pin for the NAND erase function, both of which deliver desirable performance specifications. An Error Correction Code (“ECC”) algorithm is preferably used with compute platform 215.

FIG. 2 illustrates an electrical block diagram of computation storage device 100. Computation storage device 100 is a radiation tolerant data storage device. In one embodiment, computation storage device 100 includes connector 205, power supplies 210, heterogeneous compute platform 215, telemetry subsystem 250, NAND flash chips 255, and Not-Or (“NOR”) flash 260. Power supply 210 provides connector 205 and computation storage device 100 with power. Power supply 210 is preferably a 12 V direct current (“DC”) source. Connector 205 interfaces with heterogeneous compute platform 215—most preferably through PCIe interface 220 and debug/test 225. PCIe interface 220 is preferably a fourth generation PCIe with eight lanes. Memory with error correcting code (“ECC”) 230 provides memory to heterogeneous compute platform 215. Memory with ECC 230 is preferably a DDR4 with ECC RAM multi-chip package (“MCP”). Computation storage device 100 preferably uses a Versal AI Edge System-On-Chip (“SoC”) for heterogeneous compute platform 215. Heterogeneous compute platform 215 communicates with telemetry subsystem 250 via inter-integrated circuit (“I2C”) 235, with NAND flash chips 255 via open NAND flash interface (“ONFI”) 240, and with NOR flash 260 via quad serial peripheral interface (“QSPI”) 245. Heterogeneous compute platform 215 can be based on the 7 nanometer (“nm”) thin vertical fin field-effect transistor (“FinFET”) process. In one embodiment, computation storage device 100 includes a dual-core ARM Cortex-A72 processor running at up to 1,300 MHz, a dual-core ARM Cortex-R5 microcontroller running at up to 600 MHz, two TMR MicroBlaze microcontrollers, AI Engines, Digital Signal Processors (“DSPs”), Field-Programmable Gate Arrays (“FPGA”) fabric, high speed differential transceivers, and a variety of peripherals. Computation storage device 100 preferably includes a silicon process that provides an increased radiation-tolerance by design compared with other models. In one embodiment, computation storage device 100 is space-grade. Each embodiment computation storage device 100 is radiation tolerant.

Computation storage device 100 preferably has a variety of design features that provide a great deal of radiation tolerance, even in the commercial variants. On the processing side, every level of internal cache has ECC. In one embodiment, the dual-core ARM Cortex-A72 has ECC for both its L1 and L2 caches. The dual-core ARM Cortex-R5 has ECC for its L1 caches and its Tightly Coupled Memory (“TCM”). A 256 KB On-Chip Memory (“OCM”) also has ECC. In radiation tests, an upset was not able to be formed in the processor with a neutron beam, almost certainly due to the extensive use of ECC.

In one embodiment, a Triple Modular Redundancy (“TMR”) MicroBlaze processor can be programmed to scrub the configuration memory of the programmable logic and monitor onboard telemetry to detect and correct radiation-induced errors.

In another embodiment, a system-on-chip (“SoC”) can be used for heterogeneous compute platform 215, which can include for example the Versal SoC, preferably in conjunction with a radiation tolerant (“rad-tolerant”) power supply 210, memory with ECC 230, not-or logic (“NOR”) flash 260, oscillators, interface circuits, and NAND flash chips 255. Multiple sources are preferably available to memory with ECC 230 for a highly integrated DDR4 memory module known as a Multi-Chip Package (“MCP”). Such chips contain multiple DDR dies along with a silicon interposer to connect them. This can provide 16 GB or more of memory with a 72-bit interface, 64-bits for data with another 8 used for ECC, operating at up to 2,400 MT/s. This drastically reduces the board area used compared to using discrete RAM chips. The extra RAM is useful for enabling more comprehensive data caching as well as the computational engine. NOR flash 260 is preferably used to store the bootloader code that is used to program and initialize heterogeneous compute platform 215. NOR flash 260 preferably has a simpler interface than NAND flash chips 255 and is more inherently immune to radiation. Because immunity to radiation is important in space-based applications, a rad-tolerant version of NOR flash 260 can optionally be used.

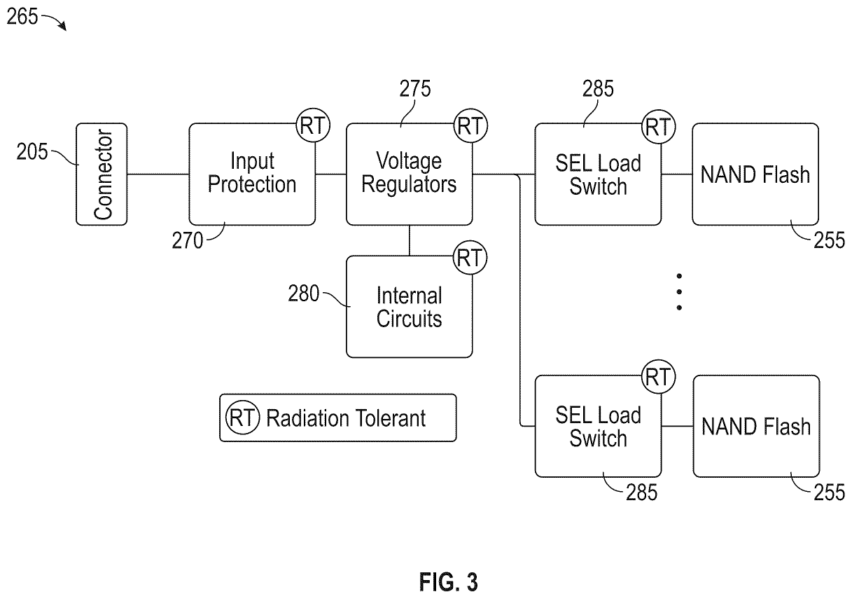

FIG. 3 is a block diagram illustrating an embodiment of electrical power system 265 for computation storage device 100. Electrical power system 265 preferably includes connector 205, input protection 270, voltage regulators 275, internal circuits 280, load switches 285, and NAND flash chips 255—all of which are radiation tolerant. In this embodiment, 12 volts direct current (“VDC”) is preferably used as the input voltage because it provides a balance between being high enough to reduce input current and low enough to easily convert to core voltages. It is also high enough to power NAND flash chips 255 and erase circuits. Recently, NAND flash chips 255 have started breaking out the flash erase power rail as a separate pin for external power, as an alternative to the built-in capacitive charge pump. In data centers on the ground, this increases power efficiency. In spacecraft, this eliminates a notorious soft spot for radiation damage.

While the primary data interface of computation storage device 100 is preferably NVMe over PCIe, it is possible to use other interfaces. The system on a chip (“SoC”), which in one embodiment, is preferably used for heterogeneous compute platform 215, supports Ethernet at about 40 gigabits per second (“Gbps”) or more, specifically 40GBASE-SR4, with a hardened system built in can be used. It is also possible to use soft cores to implement SpaceFibre and RAPIDIO, a registered trademark of Robotic Processing Solutions, Inc. using the existing super speed transceivers. Lower bandwidth protocols, including for example Gigabit Ethernet (1000BASE-T), SpaceWire, and RS-422, can be implemented using the SoC's high speed input/output (“IO”) and minimal external circuitry.

Telemetry subsystem 250 of computation storage device 100 also provides desirable results over traditional commercial off the shelf (“COTS”) SSDs. Like most other drives, computation storage device 100 preferably uses self-monitoring, analysis, and reporting technology (“SMART”). Typically, such SMART systems provide only basic information through a standardized interface. Internally, however, the controller often has access to far more data. For example, computation storage device 100 can preferably monitor every power rail, including voltages and currents, multiple temperature sensors, error detection and correction rates for both DDR4 RAM and the NAND flash, and write and erase times for the NAND flash. All of this data can be made available to users to integrate into their spacecraft-wide telemetry recording and reporting systems.

Computation storage device 100 also provides unused computational resources for users as a computational engine. In particular, in one embodiment, the dual core ARM Cortex-A72 CPUs and the AI Engines can be available for use by the user. The dual core ARM Cortex-R5 microcontrollers and some of the FPGA fabric can also be available for use by the user. Normally, these sections of the chip can be powered down to reduce power consumption. However, power supply 210 of computation storage device 100 is preferably configured to support their simultaneous operation with SSD functions. For example, this can be accomplished by providing an embedded Linux distribution that runs on the Processing Core Complex within computation storage device 100. The Computational Engine can be made available as another PCIe device using the same physical interface or via an entirely separate physical interface. This provides additional general-purpose computational resources the host spacecraft can offload to computation storage device 100. In one embodiment, data can be processed on NAND flash chips 255 directly. This computation can be configured to occur in the background on a schedule or as data is cached. This method avoids needing the overhead of transporting data to a processor external to computation storage device 100 and can even eliminate the need for an external data processor entirely, depending on the configuration of the satellite.

The form factor of computation storage device 100 is favorable to both SmallSats and CubeSats. For example, in one embodiment, the area of PCB 140 is preferably not more than about 96 millimeters (“mm”)×90 mm with a maximum thickness, including components of not more than about 15 mm. In one embodiment, a single heat spreader can be provided to take heat from computation storage device 100 to the spacecraft's chassis. In one embodiment, connector 205 is preferably selected jointly with the customer for a particular application to avoid the need for the customer to use adapters. In one embodiment, a SEARAY 0.8 MM series connector from Samtec can optionally be used. This connector provides a high density of pins in a small area, a physically robust connection, and support for both 28 Gbps data and 1.3 A/pin for high power. In one embodiment, for customer missions, the connector is preferably customized for the specific use case. This avoids the need for an electrical interface PCB, which can degrade signal integrity and increase the volume needed.

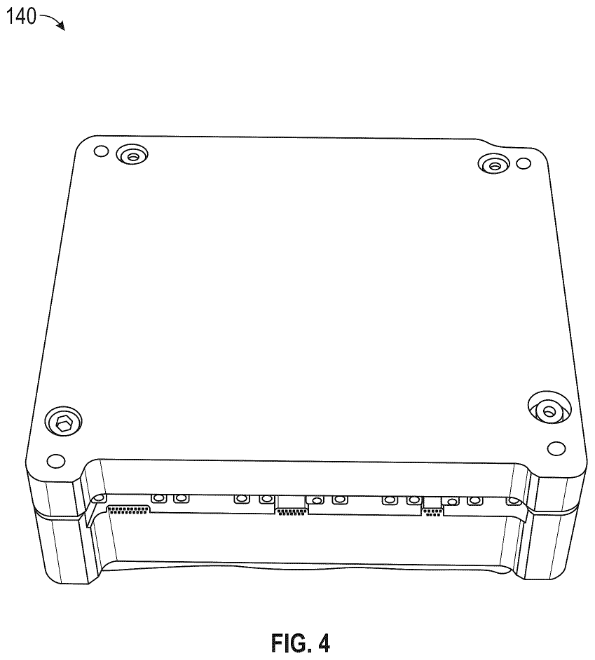

FIG. 4 illustrates an example of a complete PC104 form factor product version of PCB 140. It uses the PC104 outline and mounting hole pattern with advanced electrical connectors. In one embodiment, the complete unit is a one third U form factor that is about 33 mm tall, including the enclosure, which doubles as a heat spreader.

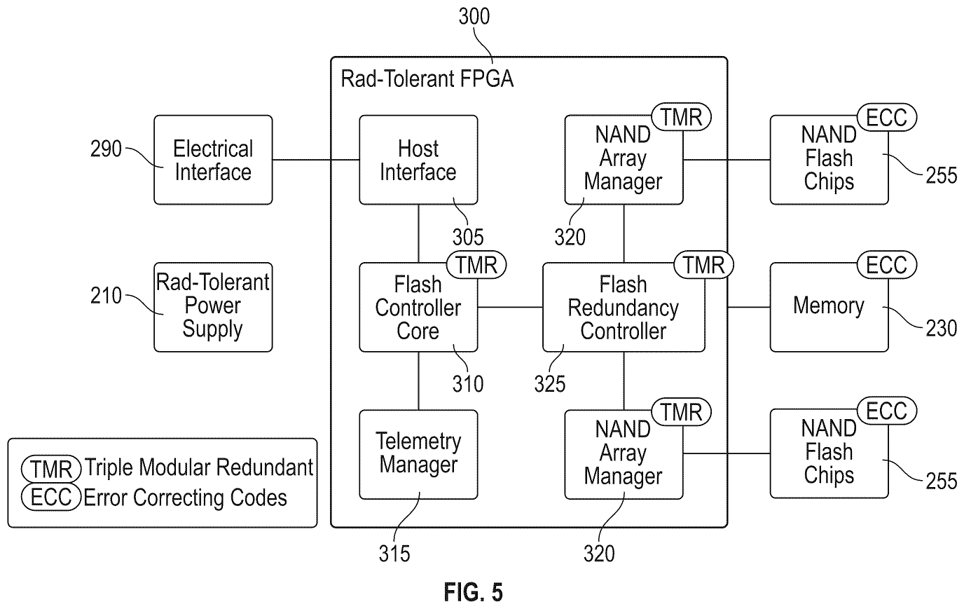

FIG. 5 illustrates a simplified model of the data flow through an embodiment of computation storage device 100. Computation storage device 100 provides redundancy and reliability while maintaining high performance. Data flow through computation storage device 100 includes electrical interface 290, power supplies 210, FPGA 300, NAND flash chips 255, and memory 230—all of which are radiation tolerant. Electrical interface 290 communicates with FPGA 300, where FPGA 300 includes host interface 305, flash controller core 310, telemetry manager 315, NAND array managers 320, and flash redundancy controller 325. FPGA 300 is also radiation tolerant. At a high level, in one embodiment, data flow through computation storage device 100 includes two redundant strings of NAND array managers 320 and NAND flash chips 255 coordinated by a TMR core. In one embodiment, each string includes its own hardware to manage the NAND arrays, via NAND array managers 320, with independent connections to its own NAND flash chips 255. The electrical power to the NAND flash chips 255 is preferably independent, so even in the case of a radiation induced power cycle of one string's NAND, the other string can carry on. Each NAND array manager 320 is preferably implemented as a TMR microcontroller. This physically spreads out the computation and provides a method of detecting a radiation-induced upset.

Computation storage device 100 preferably implements a write-through cache by default. During a write, data preferably enters the drive through host interface 305, which can be an NVMe interface, and is temporarily cached in memory 230, which can be DDR4 RAM. Then, flash controller core 310 distributes the data to each NAND array manager 320, which preferably adds error correction codes and writes both to a known good location in NAND flash chips 255. The data preferably remains cached in memory 230 for a period of time, but data can preferably be written to NAND flash chips 255 regardless in order to mitigate against an unexpected loss of power or radiation-induced upset. Data is preferably read similarly, with each NAND array manager 320 retrieving data from NAND flash chips 255. Computation storage device 100 preferably then compares the results and checks for errors before adding the data to be cached in memory 230 and transmitting it over to an NVMe interface.

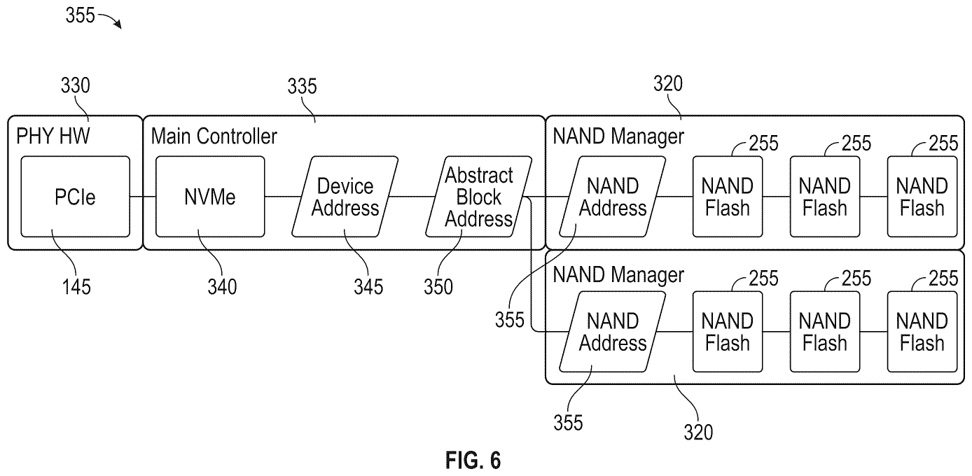

FIG. 6 illustrates an exemplary embodiment of NAND address translation 355 of computation storage device 100. NAND address translation 355 preferably includes physical layer hardware (“PHY HW”) 330, main controller 335, and NAND array managers 320. PHY HW 330 preferably includes primary data interface 145. Main controller 335 includes NVMe 340, device address 345, and abstract block address 350. Each NAND array manager 320 preferably includes NAND address 355 and NAND flash chip 255. Each of the blocks in FIG. 6 represents a microcontroller running firmware to make decisions about how to organize the data. In one embodiment, this refers to all the blocks after PHY HW 330, which are primary data interface 145 included in heterogeneous compute platform 215. However, the data itself preferably does not flow through the microcontrollers directly. All data preferably flows through direct memory access (“DMA”), which provides a high-bandwidth path through computation storage device 100. Additionally, encoding and decoding the error correcting codes is preferably implemented in hardware in the FPGA fabric, rather than through firmware running in the microcontrollers. The switching frequencies can optionally be set to over 1 GHz, and the parallel nature of the FPGA fabric and the internal connections can provide high bandwidth. In this configuration, NAND flash chips 255 can be the bottleneck for performance.

To achieve the topologically aware data placement, the file systems idea of data address is preferably remapped to an intermediate address that can be used as a starting point for NAND array managers 320 to coordinate on spreading the data out to reduce the window a high energy particle would have to hit to cause data loss—thus, as data flows through the system, it is represented by different addresses. In one embodiment, the main controller 335 preferably includes its own address map, device address 345, which it uses when communicating with the drive. This is preferably done through NVMe 340 over primary data interface 145 (or PCIe) in the default configuration. This provides a single address to the host, abstract block address 350, hiding the complexity of multiple redundant copies and ECC. In most commercial SSDs, this device address would be mapped to one or more NAND addresses 355, and the data written to NAND flash chips 255. However, in one embodiment, the present invention adds an intermediate step to enable multiple redundant NAND array managers 320. Device address 345 is preferably mapped to abstract block address 350 by main controller 335, then to NAND address 355 by each NAND array manager 320.

Abstract block addresses 350 are preferably used due to the presence of multiple NAND array managers 320 each storing the same data. In a conventional design, device addresses 345 can be directly mapped to NAND addresses 355. A single NAND array manager 320 preferably keeps track of known bad blocks, performs wear leveling, and identifies new bad blocks. With multiple NAND array managers 320, this gets more complicated. For example, each string of NAND includes its own list of bad blocks that need to be accounted for. An approach of simply mirroring NAND addresses 355 can be used, but preferably marks bad blocks from one string as bad on the other string, regardless of their status on the other string. This effectively doubles the wear from NAND flash chips 255 that the drive experiences.

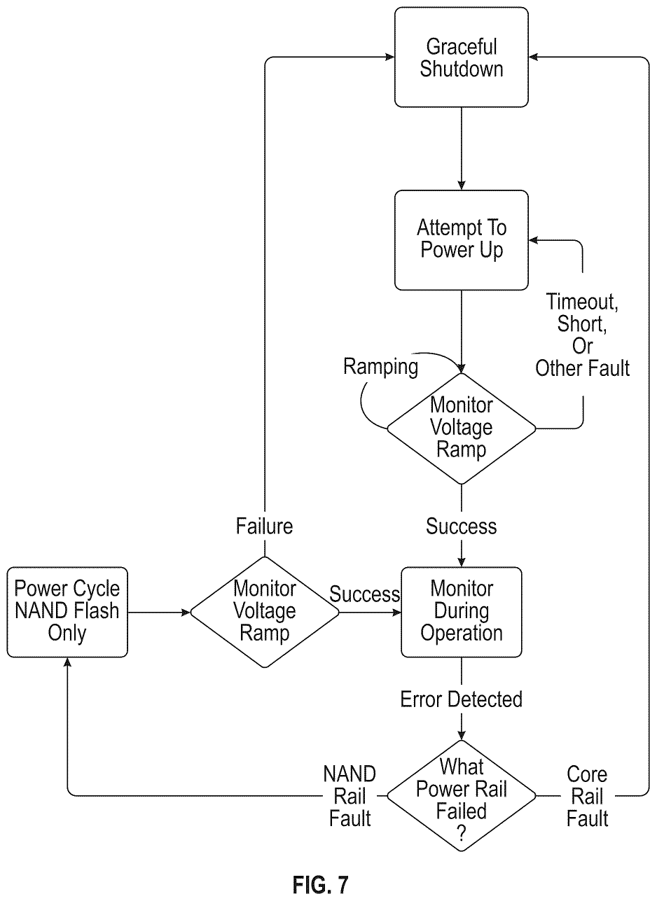

Referring now to FIG. 7, because power supply 210 can represent a single point of failure, special attention is preferably paid to its configuration. Some power supplies 210 and load switches 285 are capable of detecting the signature of a radiation-induced Single Event Latch-up (“SEL”) and can be used. This failure mode can be especially damaging, as the high currents it induces can permanently destroy hardware. This detection technology is more sensitive and precise than a simple current limit, thus allowing the system to safely power down rather than risk physical damage. While power cycling is undesirable, it is preferable to powering down permanently. Power supply 210 can be split between the core rails that power chips like the SoC and RAM and the peripheral rails that power chips like the NAND flash. Subsystems are preferably isolated with load switches 285. This allows power cycling of individual NAND chips, or small groups of NAND chips, without rebooting the entire system. A controller handles these temporary failures.

Upon the initial application of external power, a small autonomous power converter preferably provides power to the controller. The controller then enables the various power rails in a pre-programmed sequence. As each power rail is enabled, its voltage should ramp from zero to its set point within a specified time window. The controller preferably monitors this ramp and checks for a short circuit or over-current condition. Assuming everything is working properly, the system will power up completely. If there is an error, the controller can disable any enabled power supplies in the reverse order to power down the system before trying to power it up again. During operation, the controller can monitor for various error conditions-for example, under-voltage, over-voltage, over-current, and even look for the signature of a Single Event Latch-up (“SEL”). If it detects a fault, its behavior can be dependent on the power rail that is experiencing the issue. If the fault is on a power rail specific to a group of NAND flash chips, that group can be power cycled to clear the error without interrupting the operation of the core system. This allows the core system to continue providing uninterrupted service, albeit potentially at reduced performance, while the group of NAND chips is rebooted. If the fault is on a core power rail, the controller can initiate a graceful shutdown. If the fault was short enough and normal operation is restored, the controller can signal the main system to finish its tasks before powering down. If the fault is persistent, the controller will preferably begin disabling the power rails in a pre-programmed sequence. Once the system is powered down, the controller can attempt another power up sequence. The controller can also intentionally power down groups of NAND chips to minimize the long-term effects of radiation. This removes the bias of their circuits, making them less susceptible to damage. This functionality is preferably controlled by the main system via commands to the power controller. The decision to enable this feature is made depending on the mission requirement of capacity versus radiation tolerance. Power supplies 210 and the load switches 285 are preferably rated to 60 to about 110 million electron volts×cubic centimeter per milligram (“MeV-cm2/mg”) for Single Event Effects (“SEE”) and about 100,000 to about 200,000 rad for Total Ionizing Dose (“TID”).

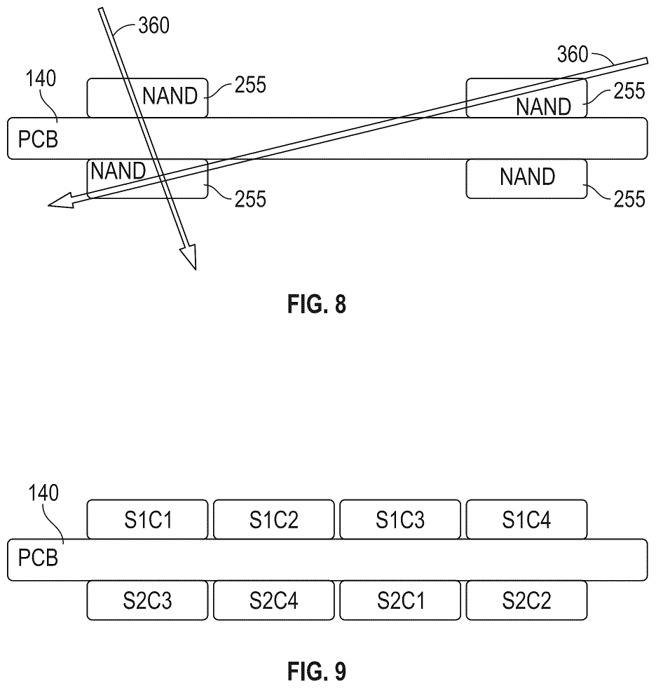

Referring now to FIGS. 8 and 9, another advantage of using abstract block addresses 350 is that it enables sophisticated techniques to increase reliability. One such technique is careful placement of data within physical space. This provides a defense against high-energy particles 360, which tend to do damage in a single line (see FIG. 8). Algorithms are preferably provided to mitigate the risk of this type of damage by ensuring that data and its mirrors or parity are not stored in a colinear arrangement in physical space. One such algorithm involves arranging the data of each of the dual redundant strings from NAND flash chips 255 on separate sides of PCB 140. Then, the data is arranged sequentially for one string, alternating between data and parity. For example, the first NAND flash chip 255 in the sequence stores some data and the second NAND flash chip 255 stores parity data. Finally, the sequence for the other string can be offset from the first string. For example, as shown in FIG. 9, there can be a first string and a second string on PCB 140, where the first string has four NAND flash chips 255 (S1C1, S1C2, S1C3, S1C4) and the second string also has four NAND flash chips 255 (S2C1, S2C2, S2C3, S2C4). Therefore, if S2C1 is placed directly opposite S1C3, then S2C2 is placed opposite S1C4, and so forth.

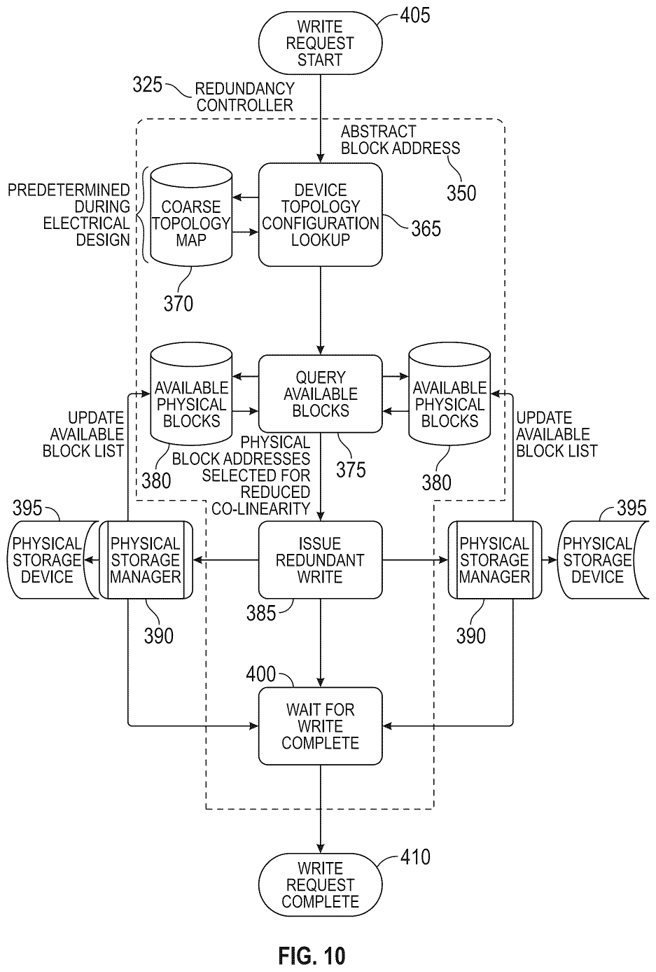

In another embodiment, redundancy controller 325 preferably compares lists of blocks in each string, as illustrated in FIG. 10. In this embodiment, write request start 405 transmits abstract block address 350 into redundancy controller 325. Redundancy controller 325 includes device topology configuration lookup 365, which transmits back and forth with course topology map 370. Course topology map 370 can include a predetermined configuration. A query is then made of available blocks 375 before the method then checks two instances of available physical blocks 380. Physical block addresses are selected for reduced collinearity after query of available blocks 375 before the redundant write 385. Redundant write instructions are issued to two instances of physical storage manager 390. Each physical storage manager 390 is in communication with physical storage device 395. Each physical storage manager 390 also updates the available block list and sends this information to redundancy controller 325. The system then waits for write complete 400 and exits redundancy controller 325 when the write request is complete 410. Considering the physical location of the blocks, if the blocks are available for writing new data, and if those particular blocks are located within an area that is busy with other operations, redundancy controller 325 computes an optimal pair of blocks given the previous computations, then issues commands to each of the storage managers to write the data to those blocks. For example, if data is currently being written or erased from a most desired data location and is thus temporarily unavailable for storage of the data at that location, rather than queue the data in a buffer and wait until the location becomes available for writing, the system can instead calculate a next best location that is currently available and then immediately have the data stored there. An increment in size between a single block and a whole chip can ease the computation.

In one embodiment, when using Low Density Parity Check (“LDPC”) codes, there are no separately encoded data and parity segments. Instead, the data is expanded into a larger section of redundant information through the LDPC algorithm and stored as a single packet of information. This packet can be stored twice on each string to enable the same algorithm as above, with four copies of the data stored in a way that is not colinear. To increase capacity, a single copy can be stored on each string, but the encoding scheme is preferably configured to provide resiliency against a single hit from a beam of radiation. The LDPC decode logic can use information from neighboring bits to reconstruct a group of bits that were affected by radiation. In one embodiment, to improve read speeds when radiation damage has not occurred, the data can also be stored with a cyclic redundancy check (“CRC”). This check can detect errors with minimal computational requirements, but it cannot correct those errors. However, if the CRC passes, the reconstruction process can be skipped, significantly improving read speeds on average. If an error is identified in a group of bits on a first chip, they can be rewritten with the corresponding group of bits from the other storage location, which can include for example the other string.

In one embodiment, when only one copy of the data is stored on each string, it is possible to minimize their exposure to radiation by careful placement relative to each other. The data is stored in a finite area within NAND flash chips 255. If each string is limited to placing data on one side of PCB 140, then the angles of radiation that can cause damage to both copies are dependent on the separation. By maximizing the horizontal separation of the copies of the data on each string, the susceptibility to radiation damage is minimized. This can include mapping NAND addresses 355 to a physical location within the chip and the placement of the chip on the printed circuit board assembly (“PCBA”). The advantage of this approach is that no single beam of radiation damage can destroy all copies of the data. Using this configuration, the data is able to be reconstructed after a hit from a high-energy particle.

In one embodiment, a third copy of the data can optionally be provided. For embodiments wherein only two copies of the data are stored across both strings of NAND, data reliability is sufficient because the data is also covered by error correcting codes before being stored in NAND flash chips 255. A large number of cells within the flash devices are used to sustain failures before rendering the system unable to re-construct and correct errors. The dual string topology guards against total failure of any single NAND flash chip 255 in the arrays.

To fully defend against colinear damage, there are preferably at least three copies of the data. This is preferably accomplished by having each NAND array manager 320 store two copies of the data on separate NAND flash chips 255 for a total of four copies of the data, each on different chips. If each NAND array manager 320 controls NAND flash chips 255 on only one side of PCB 140, it is impossible for a single beam to destroy all copies of the data.

Embodiments of the present invention provide defenses against high-energy particle beams. In another embodiment, the drive's capacity is reduced by a factor of four. An individual can choose to only store two copies of the data, one through each NAND array manager 320, but to coordinate their physical placement to minimize the angles a beam needs in order to cause an upset or destroy multiple NAND flash chips 255. The range of angles that intersect with two NAND flash chips 255 on opposite sides of PCB 140 is maximized when they are preferably located directly opposite each other (down and to the right high-energy particles 360 beam in FIG. 8) and minimized when they are spread out (to the left and down high-energy particles 360 beam in FIG. 8). This provides a statistical defense against particles powerful enough to kill multiple NAND flash chips 255 while the error correction codes provide a statistical defense against less energetic particles that can only induce bit flips. Embodiments of the present invention thus provide the ability to tune the configuration to trade capacity, performance, and reliability.

Embodiments of the present invention preferably use Low Density Parity Check (“LDPC”) codes to provide error correction for the data stored in NAND flash chips 255. This is contrary to many modern SSDs, which use Bose, Chaudhuri, Hocquenghem (“BCH”) codes. BCH codes can correct multiple-bit errors, both clustered and scattered, and is relatively efficient in terms of computational power. LDPC codes are even more efficient, both in terms of computational power and with respect to data overhead. With long blocks, LDPC codes can approach the Shannon limit-the maximum rate data can be transmitted over a channel with a given noise level. Additionally, LDPC codes can decode both hard-bit and soft-bit information on NAND flash chips 255. This allows the decoder to use reads at multiple voltage levels to distinguish adjacent digital values more accurately. For example, by using soft decoding or soft sensing in order to more accurately read the data at the cost of time and power. In one embodiment hard decoding is preferably used and a check is made if the data is correct with the parity information. If it is, nothing further needs to happen for storage of that data. If it is not, however, the soft decoding is preferably performed. These advantages provide an outsized advantage when increasing drive capacity by moving to higher density 3D NAND.

Within LDPC algorithms, there are many codes to choose from, providing a balance between redundancy and capacity. In one embodiment, the code is selected based on its function of use, the radiation environment, drive age, and preferences based on a particular application. For example, in one application, a filesystem can be stored for a critical system, including for example a payload controller, wherein the user will prefer to trade capacity for increased reliability. On the other hand, a user who is storing synthetic aperture radar (“SAR”) data will likely be willing to tolerate some number of bit flips in the data in exchange for increased capacity. The code can also be a function of the target orbit and the radiation environment there. High altitude orbits-for example those crossing through the radiation belts, sometimes need more redundancy than low inclination, low altitude orbits. NAND flash chip 255 itself physically ages with continued use. This can reduce the voltage differences between neighboring digital codes, potentially introducing errors. Embodiments of the present invention can mitigate this effect by a user choosing progressively more redundant codes throughout the lifetime of the drive.

Error correcting codes are not always enough to guarantee data integrity, especially in a high radiation environment. Larger hardware failures, for example, losing anything from a whole page to an entire die, can cause a catastrophic loss of data. The commercial SSD market is solving this problem by implementing a solution similar to a Redundant Array of Disks (“RAID”) called a Redundant Array of Independent Silicon Elements (“RAISE”). In that configuration, data is stored on one die with its parity data stored on another. If either die fails, all the data can be reconstructed. Embodiments of the present invention, however, take this technique a step further with independent NAND array managers 320 storing duplicate copies of the data. Each manager preferably includes its own communication bus to its NAND flash chips 255. This defends against not only a die failure, but also a Single Event Functional Interrupt (“SEFI”), other failure within NAND array manager 320, or even damage to the electrical bus used for communication between NAND array manager 320 and its NAND flash chips 255. NAND array managers 320 report to a single Main Controller, which is designed in a TMR configuration, allowing it to continue functioning even with a failure of one of its three redundant cores. This design allows computation storage device 100 to continue to operate with up to half its NAND flash chips 255 failed. Optionally, more than two independent strings of NAND array managers 320 with their NAND flash chips 255 can be used to provide further redundancy.

Although it is true that any two infinitesimally small points will always be equally collinear regardless of their location or separation distance, when the application describes seeking to reduce or minimize collinearity of copies of data by moving them apart from one another physically, this does reduce collinearity because the data storage for even a single bit of information is not infinitesimally small and thus does have a definite area and/or volume. Thus, as those two data storage locations separate from one another it reduces the number of straight-line beams that can intersect both copies and thus does reduce collinearity as that them is used throughout this application.

In some non-Earth-based applications, where sensing with a low signal-to-noise ratio is desired, it can be impractical to downlink, to Earth, the quantity of data needed to make a detection. In such applications, onboard processing can enable such a discovery. Robotic spacecraft scouting for resources, for example, can be made more automated and use their downlink bandwidth more efficiently by using embodiments of the present invention. Proximity operations, for example, docking spacecraft and grappling with robot arms, will need some degree of autonomy to maintain safe operations with even a few seconds of light-speed delay. Terrain relative navigation allows for precision landing near science objectives or other spacecraft but needs onboard processing due to the high volume of data and strict latency requirements. All of these applications use a large capacity of onboard data storage. Embodiments of the present invention can provide high-capacity, reliable storage with a high-bandwidth interface, while also enabling new architectures with the inclusion of high-performance compute resources at the drive level.

Embodiments of the present invention can be tuned for various particular applications. For example, Earth observation applications can benefit from higher sequential read and write speeds at the expense of reducing performance for random operations. Conversely, a customer using the drive to store a file system would want the opposite. Embodiments can also enable special modes, for example, prewarming caches for burst reads to make best use of limited downlink windows. Finally, advanced computing resources can be made available to end users, enabling computational storage with dedicated AI processors.

Optionally, embodiments of the present invention can include a general or specific purpose computer or distributed system programmed with computer software implementing steps described above, which computer software may be in any appropriate computer language, including but not limited to C, C++, FORTRAN, BASIC, Java, Python, Linux, assembly language, microcode, distributed programming languages, etc. The apparatus may also include a plurality of such computers/distributed systems (e.g., connected over the Internet and/or one or more intranets) in a variety of hardware implementations. For example, data processing can be performed by an appropriately programmed microprocessor, computing cloud, Application Specific Integrated Circuit (ASIC), Field Programmable Gate Array (FPGA), or the like, in conjunction with appropriate memory, network, and bus elements. One or more processors and/or microcontrollers can operate via instructions of the computer code and the software is preferably stored on one or more tangible non-transitive memory-storage devices.

The terms, “a”, “an”, “the”, and “said” mean “one or more” unless context explicitly dictates otherwise. Note that in the specification and claims, “about”, “approximately”, and/or “substantially” means within twenty percent (20%) of the amount, value, or condition given. All computer software disclosed herein may be embodied on any non-transitory computer-readable medium (including combinations of mediums), including without limitation CD-ROMs, DVD-ROMs, hard drives (local or network storage device), USB keys, other removable drives, ROM, and firmware.

Embodiments of the present invention can include every combination of features that are disclosed herein independently from each other. Although the invention has been described in detail with particular reference to the disclosed embodiments, other embodiments can achieve the same results. Variations and modifications of the present invention will be obvious to those skilled in the art and this application is intended to cover, in the appended claims, all such modifications and equivalents. The entire disclosures of all references, applications, patents, and publications cited above are hereby incorporated by reference. Unless specifically stated as being “essential” above, none of the various components or the interrelationship thereof are essential to the operation of the invention. Rather, desirable results can be achieved by substituting various components and/or reconfiguring their relationships with one another.

What is claimed is:

1. A radiation tolerant method for storing data, the method comprising:
providing a controller;
providing a non-transitory first data storage;
providing a non-transitory second data storage physically coupling the non-transitory first data storage to the non-transitory second data storage;
programming the controller with knowledge of a spatial relationship of the non-transitory first data storage and the non-transitory second data storage; and
the controller directing copies of the data be stored at a first location of the non-transitory first data storage and at a second location of the non-transitory second data storage while reducing collinearity of the copies based at least on:
the spatial relationship, such that the distance between the first location and the second location is selected by the controller to reduce collinearity of the copies of the data;
data storage availability of the non-transitory first data storage and data storage availability of the non-transitory second data storage; and
a current ability of each of the non-transitory first data storage and the non-transitory second data storage to store a respective copy of the data at the first location and the second location.

2. The radiation tolerant method of claim 1 wherein the controller reduces collinearity by maximizing a distance between the first location and the second location.

3. The radiation tolerant method of claim 1 wherein providing the non-transitory first data storage comprises providing a solid state data storage.

4. The radiation tolerant method of claim 3 wherein the solid state data storage comprises NAND data storage.

5. The radiation tolerant method of claim 1 wherein the controller queries a data storage manager of at least one of the non-transitory first data storage and the non-transitory second data storage.

6. The radiation tolerant method of claim 1 further comprising uploading the data into the controller from a host interface.

7. The radiation tolerant method of claim 1 further comprising a data storage manager of the non-transitory first data storage and a data storage manager of the non-transitory second data storage each adding an error check code when the copies of the data are stored.

8. The radiation tolerant method of claim 1 further comprising mapping addresses of the first location and the second location with an abstract block address.

9. The radiation tolerant method of claim 8 further comprising presenting the abstract block address to a host device.

10. The radiation tolerant method of claim 1 wherein providing a controller comprises providing a flash redundancy controller.

11. The radiation tolerant method of claim 1 further comprising the controller monitoring for a signature of a single event latch-up.

12. A radiation tolerant data storage apparatus comprising:
a controller;
a non-transitory first data storage;
a non-transitory second data storage;
said non-transitory first data storage physically coupled to said non-transitory second data storage;
said controller programmed with data describing a spatial relationship of said non-transitory first data storage and said non-transitory second data storage;
said controller comprising instructions which cause it to direct that copies of the data be stored at a first location of said non-transitory first data storage and at a second location of said non-transitory second data storage while reducing collinearity of the copies based at least on:
the spatial relationship, such that the distance between said first location and said second location is selected by said controller to reduce collinearity of the copies of the data;
data storage availability of said non-transitory first data storage and data storage availability of said non-transitory second data storage; and
a current ability of each of said non-transitory first data storage and said non-transitory second data storage to store a respective copy of the data at the first location and the second location.

13. The radiation tolerant data storage apparatus of claim 12 wherein at least one of said non-transitory first data storage and said non-transitory second data storage comprises solid state data storage.

14. The radiation tolerant data storage apparatus of claim 13 wherein said solid state data storage comprises NAND data storage.

15. The radiation tolerant data storage apparatus of claim 12 wherein said controller comprises a flash redundancy controller.

16. The radiation tolerant data storage apparatus of claim 12 wherein said non-transitory first data storage comprises a first memory manager and wherein said non-transitory second data storage comprises a second memory manager.

17. The radiation tolerant data storage apparatus of claim 16 wherein said first memory manager and said second memory manager are configured to perform data error checking operations.

18. The radiation tolerant data storage apparatus of claim 12 wherein said non-transitory first data storage is disposed on a first side of a printed circuit board and wherein said non-transitory second data storage is disposed on a second side of said printed circuit board.

19. The radiation tolerant data storage apparatus of claim 12 wherein said controller assigns an abstract block address for a block address of the first location and a block address of the second location.

20. The radiation tolerant data storage apparatus of claim 12 further comprising code stored on a non-transitory computer readable medium causing said controller to monitor for a signature of a single event latch-up.
